(19) United States
(12) Patent Application Publication
(10) Pub. No.: US 2024/0377227 A1
(43) Pub. Date: Nov. 14, 2024

(54) POSITION INDICATOR, POSITION DETECTING DEVICE, AND POSITION DETECTING METHOD

(71) Applicant: Wacom Co., Ltd., Saitama (JP)

(72) Inventor: Yosuke MATSUDA, Saitama (JP)

(21) Appl. No.: 18/657,606

(22) Filed: May 7, 2024

(30) Foreign Application Priority Data
May 8, 2023 (JP) 2023-076869

(51) Int. Cl. G01D 5/20; H03K 17/56

(52) U.S. Cl. CPC G01D 5/20; H03K 17/56

(57) ABSTRACT

Provided is a position indicator including a resonance circuit including a coil, and a control circuit including a memory that stores a digital value. The control circuit further includes a switch that switches a state of the resonance circuit between a first state and a second state which are different in resonance frequencies from each other, and, at a timing when an alternating magnetic field transmitted from a position detecting device is received, the control circuit controls the switch to set the resonance circuit to the first state, and, at a timing when a digital value stored in the memory is transmitted, the control circuit controls the switch in accordance with the digital value to be transmitted.

### BACKGROUND

### Technical Field

The present disclosure relates to a position indicator, a position detecting device, and a position detecting method, and more specifically, relates to a position indicator, a position detecting device, and a position detecting method that are designed for position detection using electromagnetic induction.

### Description of the Related Art

As one method for detecting the position of a position indicator on a panel surface of a tablet terminal or the like, electromagnetic induction (electromagnetic resonance (EMR) method) has been known. An EMR-ready position indicator (hereinafter, referred to as an “electromagnetic induction pen”) has a resonance circuit that includes a capacitor and a coil disposed at a pen tip. Meanwhile, an EMR-ready tablet terminal is equipped with a position detecting device that detects the position of an electromagnetic induction pen. The position detecting device has a plurality of loop coils that are arranged in a panel surface, and a sensor controller that is connected to the plurality of loop coils.

The position detecting device has a function of transmitting an alternating magnetic field through the panel surface by causing a flow of an alternating current to flow in at least one of the loop coils. When a coil included in the electromagnetic induction pen enters the alternating magnetic field, an electromotive force is excited in the coil as a result of electromagnetic induction. With the electromotive force, a capacitor is charged. When the position detecting device stops transmitting the alternating magnetic field, an electric charge stored in the capacitor generates a current flow in the coil. As a result, an alternating magnetic field is transmitted from the electromagnetic induction pen. The position detecting device detects the position of the electromagnetic induction pen by detecting the alternating magnetic field by means of the plurality of loop coils.

Japanese Patent Laid-open No. 2019-219710 discloses an example of an electromagnetic induction pen that sends information through an alternating magnetic field which is transmitted in the abovementioned manner. In the electromagnetic induction pen disclosed in this literature, the resonance frequency of a resonance circuit is shifted from a prescribed value in accordance with a change in the capacity of a variable capacitance capacitor, the capacitance of which varies according to a writing pressure, or in accordance with on/off switching of an operation switch which is disposed on a surface of a casing.

In recent years, an electromagnetic induction pen that transmits a digital value by on-off-keying in which the correspondence of a transmission pausing state or an in-transmission state of an alternating magnetic field with “0” or “1,” respectively, is defined has been under study. However, while transmission of an alternating magnetic field from an electromagnetic induction pen is stopped, it is impossible for a sensor controller to detect the position of the electromagnetic induction pen. For this reason, in a case where the above electromagnetic induction pen is used, a period in which the electromagnetic induction pen constantly transmits an alternating magnetic field is required separately from a period in which the electromagnetic induction pen transmits a digital value. In this case, there has been a need for improvement because the frequency of conducting the position detection is reduced.

### BRIEF SUMMARY

Therefore, embodiments of the present disclosure provide a position indicator and a position detecting device by which a digital value can be transmitted while the frequency of conducting position detection is not reduced.

In addition, in a tablet terminal in which a panel surface also serves as a display surface, noise that is derived from the display (noise that is generated when a signal passes through a gate line or a source line, hereinafter, such noise will be referred to as “display noise”) is superimposed on an alternating magnetic field or a pen signal. In some kinds of such a display, the frequency of display noise overlaps the resonance frequency of a resonance circuit. This deteriorates the signal to noise ratio (SNR) of an alternating magnetic field (hereinafter, referred to as a “pen signal”) that an electromagnetic induction pen transmits to transmit a digital value.

Therefore, embodiments of the present disclosure provide a position detecting method, a position detecting device, and a position indicator by which deterioration of the SNR of a pen signal due to display noise can be prevented.

A position indicator according to one aspect of the present disclosure includes a resonance circuit including a coil, and a control circuit including a memory that stores a digital value, in which the control circuit further includes a switch that, in operation, switches a state of the resonance circuit between a first state and a second state, wherein a resonance frequency of the resonance circuit in the first state is different from a resonance frequency of the resonance circuit on the second state, and, at a timing when an alternating magnetic field transmitted from a position detecting device is received, the control circuit controls the switch to set the resonance circuit to the first state, and, at a timing when the digital value stored in the memory is transmitted, the control circuit controls the switch in accordance with the digital value to be transmitted.

A position detecting device according to the one aspect of the present disclosure is a position detecting device for detecting a position of a position indicator, the position detecting device including a loop coil that, in operation, receives an alternating magnetic field transmitted from the position indicator, and a sensor controller that, in operation, decodes a digital value transmitted from the position indicator, on the basis of a frequency of the alternating magnetic field.

A position detecting method according to another aspect of the present disclosure is performed by a position detecting device that acquires information transmitted from a position indicator equipped with a resonance circuit including a coil, by detecting an alternating magnetic field transmitted from the position indicator, the method including: switching, by the position indicator, a state of the resonance circuit between a first state and a second state, wherein a first reference resonance frequency of the resonance circuit in the first state is different from a second reference resonance frequency of the resonance circuit in the second state, and sending, by the position detecting device, to the position indicator, a switch command to make a transition of the state of the resonance circuit from the first state to the second state.

A position detecting device according to the other aspect of the present disclosure acquires information transmitted from a position indicator equipped with a resonance circuit including a coil, by detecting an alternating magnetic field transmitted from the position indicator, the position detecting device comprising: a processor; and a memory storing instructions that, when executed by the processor, cause the position detecting to: send, to the position indicator, a switch command configured to make a state of the resonance circuit transition from a first state to a second state, wherein a first resonance frequency of the resonance circuit in the first state is different from a second reference resonance frequency of the resonance circuit in the first state.

A position indicator according to the other aspect of the present disclosure includes a resonance circuit including a coil, and a control circuit, in which the resonance circuit further includes a switch that, in operation, switches a state of the resonance circuit between a first state and a second state, wherein a first resonance frequency of the resonance circuit in the first state is different from a second reference resonance frequency of the resonance circuit on the second state, and upon detection of an alternating magnetic field modulated with a control signal by the resonance circuit in the first state, the control circuit causes a transition of the state of the resonance circuit from the first state to the second state.

According to the one aspect of the present disclosure, it is possible to transmit a digital value without stopping the transmission of the alternating magnetic field from the position indicator. Accordingly, it is possible to transmit a digital value without reducing the frequency of conducting position detection.

According to the other aspect of the present disclosure, it is possible to control the resonance frequency of the position indicator through the position detecting device grasping the frequency of display noise. Accordingly, deterioration of the SNR of the pen signal due to display noise can be prevented.

### BRIEF DESCRIPTION OF THE SEVERAL VIEWS OF THE DRAWINGS

FIG. 1 is a diagram depicting a configuration of a position detecting system according to a first embodiment of the present disclosure;

FIG. 2 is a diagram depicting an internal configuration of a resonance circuit depicted in FIG. 1;

FIG. 3 is a timing chart of an alternating magnetic field and a pen signal;

FIG. 4 is a diagram depicting spectrums of display noise in two kinds of displays manufactured by different manufacturers;

FIG. 5 is a diagram depicting an internal configuration of an electromagnetic induction pen constituting the position detecting system according to a second embodiment of the present disclosure;

FIG. 6 is a diagram depicting a specific configuration example of a modulation unit depicted in FIG. 5;

FIGS. 7A and 7B are diagrams each depicting an example of the waveform of an alternating current depicted in FIG. 5;

FIG. 8 is a process flowchart indicating a process that is executed by a sensor controller according to the second embodiment of the present disclosure;

FIG. 9 is a process flowchart indicating the process that is executed by the sensor controller according to the second embodiment of the present disclosure; and

FIG. 10 is a process flowchart indicating the process that is executed by the sensor controller according to the second embodiment of the present disclosure.

### DETAILED DESCRIPTION

Hereinafter, embodiments of the present disclosure will be explained in detail with reference to the attached drawings.

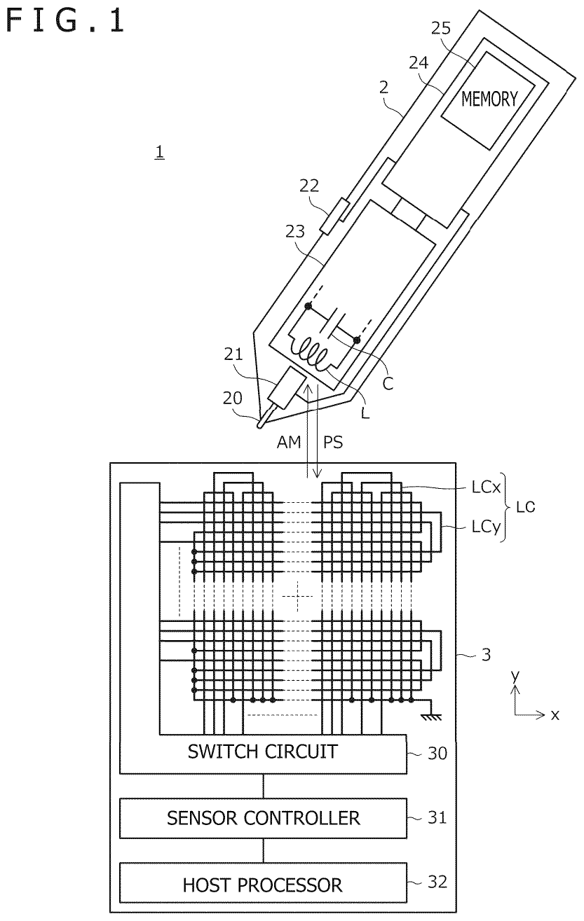

FIG. 1 is a diagram depicting a configuration of a position detecting system 1 according to a first embodiment of the present disclosure. As depicted in FIG. 1, the position detecting system 1 according to the present embodiment includes an EMR-ready electromagnetic induction pen 2 and an EMR-ready position detecting device 3. The electromagnetic induction pen 2 is a position indicator having a pen-like shape and including a core body 20, a pressure sensor 21, a side switch 22, a resonance circuit 23, and a control circuit 24. In the following explanation, an alternating magnetic field that is transmitted from the position detecting device 3 is referred to as an “alternating magnetic field AM,” and a signal that is exhibited, as a reflection signal to the alternating magnetic field AM, by the alternating magnetic field transmitted from the electromagnetic induction pen 2, is referred to as a “pen signal PS.”

The core body 20 is a rod-like member forming a pen tip of the electromagnetic induction pen 2, and is movable in the pen axis direction. A rear end of the core body 20 is in contact with the pressure sensor 21. The pressure sensor 21 detects the value (writing pressure value) of a pressure applied to the pen tip by detecting a pressing force from the rear end of the core body 20. The writing pressure value detected by the pressure sensor 21 is written into a memory 25 that is included in the control circuit 24.

The side switch 22 is an on-off type switch that is disposed on a surface of the electromagnetic induction pen 2, and is configured to generate information (on-off information) indicating the on-off state of the side switch 22 itself. The on-off information generated by the side switch 22 is also written into the memory 25 that is included in the control circuit 24. It is to be noted that FIG. 1 illustrates the electromagnetic induction pen 2 that has one side switch 22, but the electromagnetic induction pen 2 may have a plurality of the side switches 22. In addition, a similar switch may be disposed on a surface (e.g., end portion) other than the side surface of the electromagnetic induction pen 2.

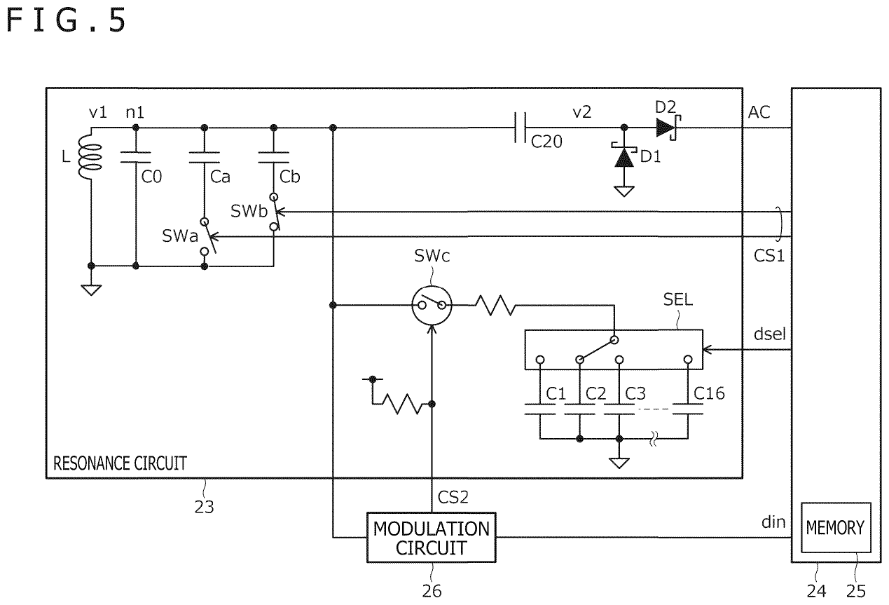

The resonance circuit 23 is an integrated circuit including an LC resonance circuit formed of a coil L and a capacitor C that are connected in series. However, a portion or all of components constituting the resonance circuit 23 may be formed of elements external to the integrated circuit. The same applies to the control circuit 24 and a modulation unit 26 (see FIG. 5) which will be explained later.

The coil L is a component that is disposed near the pen tip and is brought into magnetic field coupling with loop coils LC (explained later) that are included in the position detecting device 3. When the coil L enters the alternating magnetic field AM, an electromotive force is excited in the coil L by electromagnetic induction. Accordingly, an alternating current is generated in the resonance circuit 23, and further, power is stored in the capacitor C. The resonance circuit 23 supplies the generated alternating current to the control circuit 24, and has a role of transmitting a pen signal PS as a reflection signal by using the power stored in the capacitor C after the alternating magnetic field AM disappears.

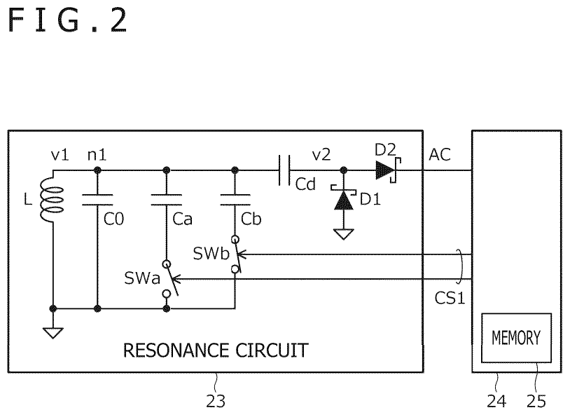

FIG. 2 is a diagram depicting an internal configuration of the resonance circuit 23. As depicted in FIG. 2, the resonance circuit 23 includes the coil L, capacitors C0, Ca, Cb, and Cd, diodes D1 and D2, and switches SWa and SWb.

This coil L is identical to that depicted in FIG. 1, and is connected between a node n1 and a grounded end depicted in FIG. 2. The capacitor C0 is a capacitor constituting a part of the capacitor C depicted in FIG. 1, and is connected between the node n1 and the grounded end. As a result of these connections, the LC resonance circuit including the coil L and the capacitor C0 is formed.

The capacitor Cd is a decoupling capacitor that is inserted at a certain point on a wire connecting the node n1 and the control circuit 24. The capacitor Cd plays a role of converting an alternating current v1 (a voltage signal that oscillates around 0V) appearing in the node n1 to an alternating current v2 oscillating in a positive-side range by applying a direct voltage to the alternating current v1.

The diode D1 is a Schottky barrier diode that has a role of preventing a surge current from flowing into the control circuit 24. The cathode of the diode D1 is connected to a control circuit 24-side electrode of the capacitor Cd, and the anode of the diode D1 is grounded. The diode D2 is a Schottky barrier diode that has a role of rectifying a current flowing into the control circuit 24. The cathode of the diode D2 is connected to a control circuit 24-side electrode of the capacitor Cd, and the anode of the diode D2 is connected to an input end of the control circuit 24. A current having passed through the diode D2 is supplied as an alternating current AC to the control circuit 24.

The capacitor Ca and the switch SWa are connected in series between the node n1 and the grounded end. Likewise, the capacitor Cb and the switch SWb are connected in series between the node n1 and the grounded end. When the switch Swa is on, the capacitor Ca is connected in parallel with the capacitor C0 so that the capacitor Ca and the capacitor C0 form the capacitor C which is depicted in FIG. 1. Likewise, when the switch SWb is on, the capacitor Cb is connected in parallel with the capacitor C0 so that the capacitor Cb and the capacitor C0 form the capacitor C which is depicted in FIG. 1.

The switches SWa and SWb function in combination as one switch that plays a role of switching the state of the resonance circuit 23 between two states that are different in resonance frequencies from each other. Specifically, in accordance with a control signal CS1 supplied from the control circuit 24, the switches Swa and SWb are controlled such that either one of the switches is on while the other switch is off. Hereinafter, a state where the switch Swa is off while the switch SWb is on is referred to as a “first state,” and a state where the switch Swa is on while the switch SWb is off is referred to as a “second state.” Further, the resonance frequency of the resonance circuit 23 that is in the first state is referred to as a “first frequency,” and the resonance frequency of the resonance circuit 23 that is in the second state is referred to as a “second frequency.” It is preferable that the first frequency have a value equal to that of the frequency of the alternating magnetic field AM (a reference frequency for modulation if frequency modulation is performed on the alternating magnetic field AM) transmitted by the position detecting device 3. The respective capacitances of the capacitors Ca and Cb are designed such that the value of the first frequency is sufficiently apart from the value of the second frequency (that is, the values are so apart from each other that the position detecting device 3 having received the pen signal PS can identify the frequency of the pen signal).

The switch Swa is formed of a normally-off field effect transistor that is off when a gate voltage is 0. On the other hand, the switch SWb is a normally-on field effect transistor that is on when a gate voltage is 0. Accordingly, the initial state of the resonance circuit 23 is the first state.

Referring back to FIG. 1, the control circuit 24 is an integrated circuit including the memory 25, and is configured to work with power obtained from the alternating current AC. A digital value to be transmitted from the electromagnetic induction pen 2 to the position detecting device 3 is stored in the memory 25. Specifically, a digital value indicating the abovementioned writing pressure value, a digital value indicating the abovementioned on-off information, and further, a digital value indicating a pen identification (ID) which is information for identifying the electromagnetic induction pen 2, etc., are stored in the memory 25.

Referring back to FIG. 2, the control circuit 24 is configured to, at a timing when the alternating magnetic field AM transmitted from the position detecting device 3 is received, control the switches Swa and SWb to set the resonance circuit 23 to the first state, and to, at a timing when a digital value stored in the memory 25 is transmitted through the pen signal PS, control the switches Swa and SWb in accordance with the digital value to be transmitted. Accordingly, at a timing when the alternating magnetic field AM is received, the electromagnetic induction pen 2 can adjust the resonance frequency of the resonance circuit 23 to match the frequency of the alternating magnetic field AM, and further can modulate the pen signal PS (frequency modulation) in accordance with the digital value.

A more specific explanation will be given. Upon start of supply of the alternating current AC from the resonance circuit 23, the control circuit 24 demodulates the supplied alternating current AC, whereby obtains a command transmitted from the position detecting device 3. Then, in accordance with the obtained command, the control circuit 24 decides a set of digital values to be transmitted to the position detecting device 3. Further, when the alternating current AC is being supplied from the resonance circuit 23, the control circuit 24 monitors the amplitude of the alternating current AC. If reduction in the amplitude of the alternating current AC beyond a prescribed range is detected as a result of the monitoring, the control circuit 24 determines that transmission of the alternating magnetic field AM from the position detecting device 3 is finished. Thereafter, by using the control signal CS1, the control circuit 24 starts controlling the switches Swa and SWb on the basis of the set of digital values to be transmitted to the position detecting device 3.

Transmission of the set of digital values under control of the control circuit 24 is performed one bit by one bit serially. That is, the control circuit 24 controls the switches Swa and SWb to set the resonance circuit 23 to the first state when a bit “0” is transmitted, and to set the resonance circuit 23 to the second state when a bit “1” is transmitted. It is reasonably to be noted that the control circuit 24 may control the switches Swa and SWb to set the resonance circuit 23 to the first state when a bit “1” is transmitted, and to set the resonance circuit 23 to the second state when a bit “0” is transmitted. Since the control circuit 24 performs this control, the frequency of the pen signal PS transmitted from the electromagnetic induction pen 2 is sequentially changed between the first frequency and the second frequency in accordance with the set of digital values to be transmitted.

Here, it is preferable that the control circuit 24 control the switches SWa and SWb at a timing when the value of the alternating current v1 flowing through the resonance circuit 23 becomes 0. If so, the switches Swa and SWb can be turned on/off while no power (electric charge) is stored in the capacitor C. Accordingly, reduction of the level of the alternating current AC due to on/off switching of the switches Swa and SWb can be prevented. As a specific configuration for realizing this control, which is not depicted in FIG. 2, a configuration similar to that including the modulation unit 26 and a control signal din, which will be explained in a second embodiment, may be used.

Referring back to FIG. 1, the position detecting device 3 includes a plurality of loop coils LC, a switch circuit 30, a sensor controller 31, and a host processor 32. In a typical embodiment, the position detecting device 3 is a tablet terminal or a laptop computer having a display surface that is also used as a touch surface. Alternatively, the position detecting device 3 may be formed of a digitizer with no display surface. In one or more embodiments, the sensor controller 31 includes a processor and a memory storing instructions that, when executed by the processor, cause the sensor controller 31 to perform the acts described herein.

The plurality of loop coils LC are arranged in the touch surface, and include a plurality of loop coils LCx that are arranged side by side in an x direction and a plurality of loop coils Lcy that are arranged side by side in a y direction. Each of the loop coils LC has one end connected to the switch circuit 30, and the other end connected to the ground. The switch circuit 30 plays a role of connecting one or more of the loop coils LC to the sensor controller 31 under control of the sensor controller 31.

The sensor controller 31 is an integrated circuit having a function of deriving the position of the electromagnetic induction pen 2 on the touch surface and obtaining the set of digital values transmitted through the pen signal PS from the electromagnetic induction pen 2, and sequentially supplying the detected position and the obtained set of the digital values to the host processor 32. To perform this processing, the sensor controller 31 is configured to cause at least one of the coils LC to transmit the alternating magnetic field AM and cause each of the loop coils LC to receive the pen signal PS after the transmission of the alternating magnetic field AM is finished.

Processing that is specifically executed by the sensor controller 31 varies between at a stage where the electromagnetic induction pen 2 has not been detected (global scan) and at a stage where the electromagnetic induction pen 2 has been detected (local scan). More specifically, in a global scan, the sensor controller 31 first performs a process of sequentially causing the plurality of loop coils LC to transmit the alternating magnetic field AM and then scanning the plurality of loop coils LC sequentially or simultaneously each time transmission of the alternating magnetic field AM is finished. As a result, if the pen signal PS is detected at any one of the loop coil LC, the position of the electromagnetic induction pen 2 is derived on the basis of the reception intensities of the pen signal PS at the respective loop coils LC, and then, a transition to a local scan is made.

After the transition to the local scan, the sensor controller 31 selects at least one of the plurality of loop coils LC as a loop coil for transmission of the alternating magnetic field AM on the basis of the latest position of the electromagnetic induction pen 2 and further selects, as loop coils for reception of the pen signal PS, a plurality of loop coils LC located around the position of the latest electromagnetic induction pen 2. Thereafter, the alternating magnetic field AM is transmitted from the loop coil LC for transmission. After the transmission is finished, the loop coils LC for reception are sequentially or simultaneously scanned. On the basis of the reception intensities of the pen signal PS at the respective loop coils LC for reception, which are obtained as a result of this scanning, the sensor controller 31 derives the position of the electromagnetic induction pen 2. Further, by demodulating the pen signal PS received at the loop coil LC where the reception intensity is the highest, the sensor controller 31 obtains a set of digital values transmitted from the electromagnetic induction pen 2. If the pen signal PS is not detected at any of the loop coils LC, the sensor controller 31 makes a transition to a global scan to perform the abovementioned global scan.

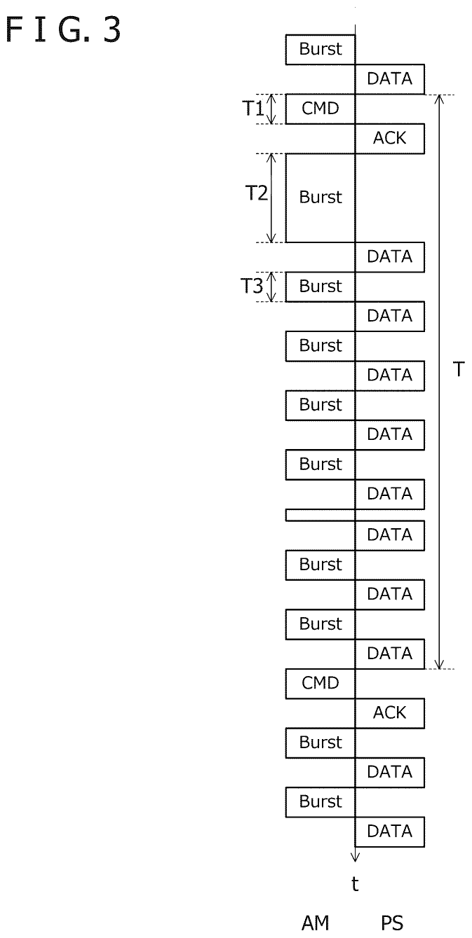

FIG. 3 is a timing chart of the alternating magnetic field AM and the pen signal PS. FIG. 3 depicts an example of a case where the sensor controller 31 performs a local scan. As depicted in FIG. 3, the sensor controller 31 is configured to perform, in a cycle T, transmission of the alternating magnetic field AM modulated in accordance with a command CMD. This transmission is performed for a prescribed time period T1.

The control circuit 24 of the electromagnetic induction pen 2 further performs a process of trying to demodulate the alternating current AC supplied from the resonance circuit 23. In a case where the alternating magnetic field AM has been modulated in accordance with the command CMD, the control circuit 24 receives the command CMD by demodulating the alternating current AC. After receiving the command CMD in this manner, the control circuit 24 of the electromagnetic induction pen 2 first transmits a response signal ACK. After receiving the response signal ACK, the sensor controller 31 causes the abovementioned loop coils LC for transmission to transmit eight Bursts, which are non-modulated alternating magnetic fields AM, at prescribed intervals. The first-time transmission of a Burst is performed for a prescribed time period T2 that is longer than the prescribed time period T1. Each of the seven remaining Bursts is transmitted for a prescribed time period T3 that is shorter than the prescribed time period T2. It is to be noted that the prescribed time period T3 may be as long as the prescribed time period T1, may be shorter than the prescribed time period T1, or may be longer than the prescribed time period T1.

During transmission of the Burst for the prescribed time period T2, the control circuit 24 of the electromagnetic induction pen 2 performs a process of generating a set of digital values to be transmitted to the sensor controller 31, on the basis of the content stored in the memory 25, while working with power generated by the alternating current AC. After generating the set of the digital values in this manner, the control circuit 24 obtains DATA which indicates four bits of a non-transmitted part of the generated set of the digital values each time detecting that transmission of Burst from the position detecting device 3 is finished through reduction of the amplitude of the alternating current AC. Then, in accordance with the obtained DATA, the control circuit 24 controls the switches Swa and SWb of the resonance circuit 23. The details of this control have been explained above. Consequently, the pen signal PS having undergone frequency modulation based on the DATA is transmitted.

The sensor controller 31 performs a process of causing the respective loop coils LC for reception to receive the pen signal PS having undergone modulation based on the DATA, deriving the position of the electromagnetic induction pen 2, on the basis of a result of the reception (i.e., the reception levels of the pen signal PS at the respective loop coils LC), and demodulating the pen signal PS received at one of the plurality of loop coils for reception. The details of this demodulation are not specifically limitative. For example, the sensor controller 31 may conduct a frequency analysis (e.g., fast Fourier transform) of the pen signal PS at every prescribed time that corresponds to an interval of transmission of 1 bit from the electromagnetic induction pen 2, and may obtain the set of digital values transmitted from the electromagnetic induction pen 2, on the basis of the reception level at each frequency obtained as a result of the frequency analysis. Alternatively, the sensor controller 31 may conduct phase detection, which will be explained in a second embodiment, at every prescribed time that corresponds to an interval of transmission of 1 bit from the electromagnetic induction pen 2, and may obtain the set of digital values transmitted from the electromagnetic induction pen 2.

According to the present embodiment, modulation of an alternating magnetic field from the electromagnetic induction pen 2 is implemented by changing the resonance frequency instead of by on-off-keying. Therefore, when the electromagnetic induction pen 2 is transmitting the pen signal PS which is DATA, an alternating magnetic field is constantly transmitted from the electromagnetic induction pen 2. Therefore, the sensor controller 31 can derive the position of the electromagnetic induction pen 2 all the while the electromagnetic induction pen 2 is transmitting DATA. It can be said that, according to the present embodiment, the frequency of position detection can be increased, compared to a case where modulation of an alternating magnetic field from the electromagnetic induction pen 2 is performed by on-off-keying.

Referring back to FIG. 1, after receiving the position and the set of digital values from the sensor controller 31, the host processor 32 performs a process of moving a cursor on the display surface or generating stroke data which indicates the path of the electromagnetic induction pen 2 on the touch surface, by using the position and the digital values. Regarding the stroke data, the host processor 32 further performs a process of rendering and indicating the generated stroke data, a process of creating and recording a digital ink including the generated stroke data, and a process of transmitting the generated stroke data to an external device in accordance with a user's instruction.

As explained so far, in the position detecting system 1 according to the present embodiment, modulation of an alternating magnetic field from the electromagnetic induction pen 2 is implemented by changing a resonance frequency instead of by on-off-keying. Accordingly, it is possible to transmit digital values from the electromagnetic induction pen 2 without reducing the frequency of conducting position detection.

With the position detecting system 1 according to the present embodiment, when the alternating magnetic field AM is received, the resonance frequency of the resonance circuit 23 can be adjusted to match the frequency of the alternating magnetic field AM. Accordingly, the alternating magnetic field AM can be efficiently received.

Next, the position detecting system 1 according to the second embodiment of the present disclosure will be explained. The position detecting system 1 according to the present embodiment is different from the first embodiment in that the resonance frequency of the electromagnetic induction pen 2 is controlled from the position detecting device 3, that the switches SWa and SWb are used (not to transmit a digital value but) to change the reference resonance frequency of the resonance circuit 23 (with respect to which, the resonance frequency of the resonance circuit 23 is modulated) under control of the position detecting device 3, and that additional components (specifically, capacitors C1 to C16, a switch SWc, a selector SEL, and the modulation unit 26 which will be explained later) for transmitting digital values are provided. Except for these differences, the system configuration depicted in FIG. 1 and the like of the position detecting system 1 according to the first embodiment are identical to the position detecting system 1 according to the present embodiment. However, the position detecting device 3 according to the present embodiment is limited to a type having a display surface that also functions as a touch surface. Hereinafter, the position detecting system 1 according to the present embodiment will be explained while attention will be given to the differences from the position detecting system 1 according to the first embodiment.

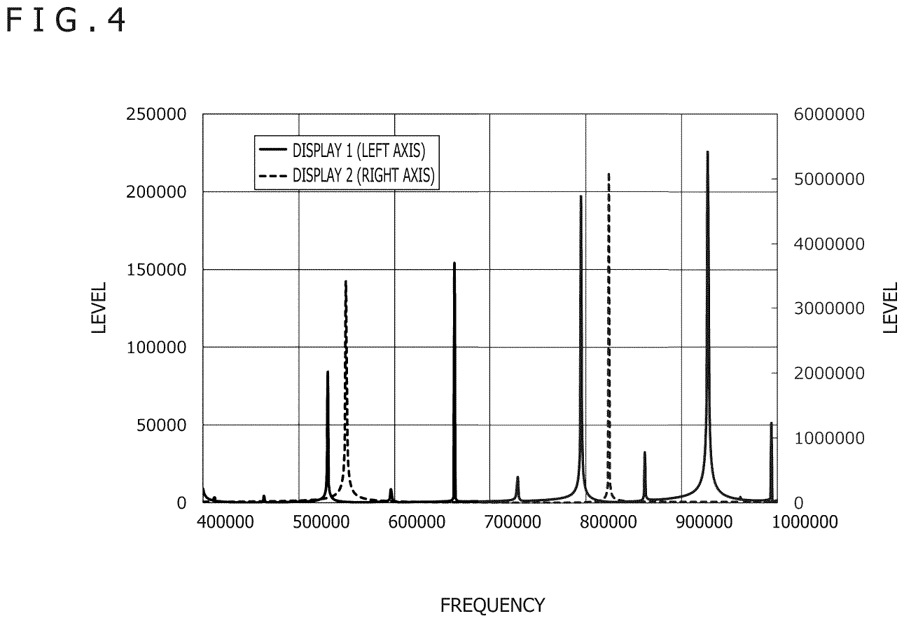

First, an outline of the position detecting system 1 according to the present embodiment will be given. FIG. 4 is a diagram depicting spectrums of display noise in two kinds of displays manufactured by different manufacturers. As is understood from FIG. 4, the frequencies of display noise usually vary by manufactures. In a certain kind of a display included in the position detecting device 3, the frequency of a pen signal PS may be identical to or close to the frequency of display noise. In this case, the SNR of the pen signal PS is deteriorated, and the sensor controller 31 has a difficulty in modulating the pen signal PS. In order to prevent occurrence of such a situation, the position detecting system 1 according to the present embodiment is configured to control the reference resonance frequency of the electromagnetic induction pen 2 from the sensor controller 31.

First of all, specifically, the electromagnetic induction pen 2 according to the first embodiment is configured in such a way that the state of the resonance circuit 23 is switchable between a first state and a second state that are different in reference resonance frequency from each other. Hereinafter, the reference resonance frequency of the resonance circuit 23 that is in the first state will be referred to as a “first reference resonance frequency,” and the reference resonance frequency of the resonance circuit 23 that is in the second state will be referred to as a “second reference resonance frequency.” The position detecting device 3 according to the present embodiment is equipped with a built-in display of a type in which display noise having a frequency identical to the first reference resonance frequency or close to the first reference resonance frequency is generated. The sensor controller 31 according to the present embodiment is configured to send, to the electromagnetic induction pen 2, a switch command to make a transition of the state of the resonance circuit 23 from the first state to the second state. The electromagnetic induction pen 2 is configured to, by switching the state of the resonance circuit 23 to the second state in accordance with the switch command, change the reference resonance frequency of the resonance circuit 23 to the second reference resonance frequency. As a result, the pen signal PS is transmitted in a frequency band that does not overlap the frequency of display noise, whereby deterioration of the SNR of the pen signal PS due to display noise can be prevented. Hereinafter, a specific configuration for implementing this operation will be explained in detail.

FIG. 5 is a diagram depicting an internal configuration of the electromagnetic induction pen 2 constituting the position detecting system 1 according to the present embodiment. As depicted in FIG. 5, the electromagnetic induction pen 2 according to the present embodiment includes capacitors C1 to C16, a switch SWc, a selector SEL, and the modulation unit 26, in addition to the components depicted in FIG. 2. The capacitors C1 to C16, the switch SWc, and the selector SEL constitute a part of the resonance circuit 23.

The switch SWc is a single-pole single-throw analog switch that is turned on/off in accordance with a control signal CS2 supplied from the modulation unit 26. The switch SWc has one end connected to the node n1, and the other end connected to a shared terminal of the selector SEL.

The selector SEL is a switch circuit having multi-contacts (specifically, 16 contacts in one circuit) switching of which is controlled by a selection signal dsel supplied from the control circuit 24. One electrodes of the respective capacitor C1 to C16 are connected to corresponding selection terminals of the selector SEL. The capacitors C1 to C16 are different in capacities from each other. The other ends of the respective capacitors C1 to C16 are all connected to the grounded end.

When the switch SWc is on, a capacitor Cx (x is any one of 1 to 16) having been selected by the selector SEL is connected in parallel with the capacitor C0, the capacitor Cx and the capacitors C0 and Ca (or the capacitors C0 and Cb) form the capacitor C which is depicted in FIG. 1. On the other hand, when the switch SWc is off, the capacitor Cx is disconnected from the capacitor C0, and the capacitor C which is depicted in FIG. 1 is formed of the capacitors C0 and Ca (or capacitors C0 and Cb) only.

Here, the control circuit 24 stores in advance a table in which a correspondence between 4-bit information and each of the capacitors C1 to C16 is defined. Then, each time DATA (data consisting of 4-bit digital values) depicted in FIG. 3 is to be transmitted, the control circuit 24 determines a capacitor Cx that corresponds to the DATA to be transmitted by consulting the table, and supplies a selection signal dsel for selecting the determined capacitor Cx to the selector SEL. Consequently, the selector SEL selects the capacitor Cx corresponding to the DATA to be transmitted, and the capacitance of the capacitor C has a value corresponding to the 4-bit digital values to be transmitted. As a result, the resonance frequency of the resonance circuit 23 is changed from the prescribed reference resonance frequency by an amount corresponding to the 4-bit digital values to be transmitted.

In the present embodiment, the capacitors Ca and Cb are used not to transmit digital values but to switch the state of the resonance circuit 23 according to the frequency of display noise. Specifically, the capacitors Ca and Cb are used to switch the state of the resonance circuit 23 between the first state in which the reference resonance frequency is set to the first reference resonance frequency and the second state in which the reference resonance frequency is set to the second reference resonance frequency.

In the first state, the switch SWa is off while the switch SWb is on. A specific value of the first reference resonance frequency is determined by an induction coefficient of the coil L and the capacitances of the capacitors C0 and Cb. It is to be noted that the first reference resonance frequency is preferably equal to the frequency of the alternating magnetic field AM (with respect to which, frequency modulation of the alternating magnetic field AM is performed) transmitted from the position detecting device 3. In the second state, the switch SWa is on while the switch SWb is off. A specific value of the second reference resonance frequency is determined by an induction coefficient of the coil L and the capacitances of the capacitors C0 and Ca.

Here, the configuration of the sensor controller 31 will be explained. The sensor controller 31 according to the present embodiment is configured to detect the pen signal PS in two different frequency bands. One of the frequency bands includes the first reference resonance frequency, and the resonance frequency range (16 kinds of resonance frequencies) of the resonance circuit 23, to which a change from the first reference resonance frequency can be made in accordance with a selection made by the selector SEL. Hereinafter, this frequency band is referred to as a “first frequency band.” The other one of the frequency bands includes the second reference resonance frequency and the resonance frequency range (16 kinds of resonance frequencies) of the resonance circuit 23, to which a change from the second reference resonance frequency can be made in accordance with a selection made by the selector SEL. Hereinafter, this frequency band is referred to as a “second frequency band.” The capacitances of the capacitors included in the resonance circuit 23 are previously set to respective values such that the first frequency band does not overlap the second frequency band.

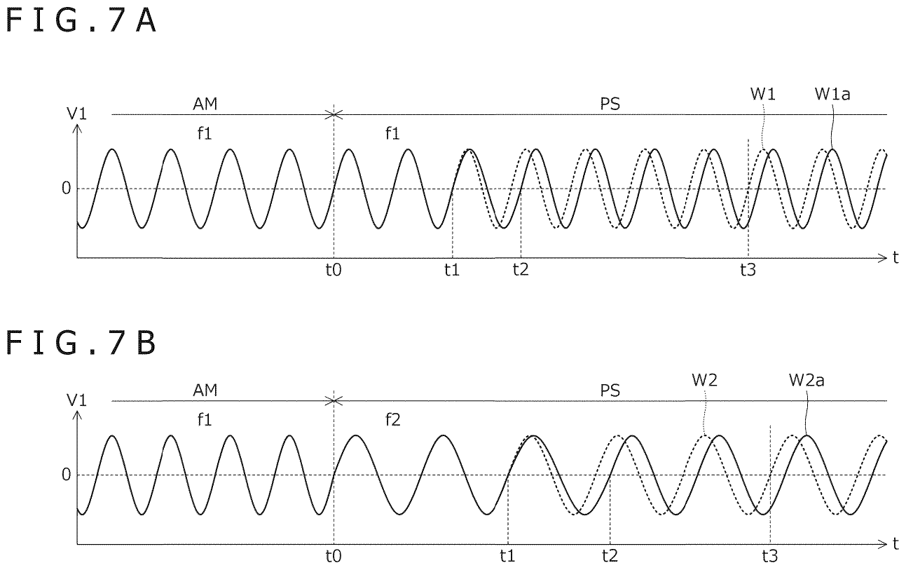

The sensor controller 31 is configured to restore a signal received in either one of the two frequency bands by conducting frequency analysis such as fast Fourier transform or discrete Fourier transform, but does not detect, as a frequency change, a slight shift of the frequency within each of the frequency bands. The sensor controller 31 is configured to detect the phase of the restored signal and obtain the digital values transmitted from the electromagnetic induction pen 2, on the basis of a result of the phase detection, instead. This will be explained in detail later with reference to FIGS. 7A and 7B.

The explanation of the internal configuration of the electromagnetic induction pen 2 will be resumed. The modulation unit 26 is an integrated circuit having a function of temporarily changing the resonance frequency of the resonance circuit 23 by performing on/off control of the switch SWc. Specifically, in an activated time period of the control signal din being supplied from the control circuit 24, the modulation unit 26 turns on the switch SWc at a timing when the value of the alternating current v1 flowing through the resonance circuit 23 becomes 0, and turns off the switch SWc at a timing when the alternating current v1 returns to 0 after the control signal din enters a non-activated state again.

The control signal din indicates that transmission of the alternating magnetic field AM is finished. The control circuit 24 is configured to, after detecting that transmission of the alternating magnetic field AM from the position detecting device 3 is finished by detecting reduction in the amplitude of the alternating current AC, make the control signal din active for a time period that is slightly shorter than one cycle of the alternating magnetic field AM.

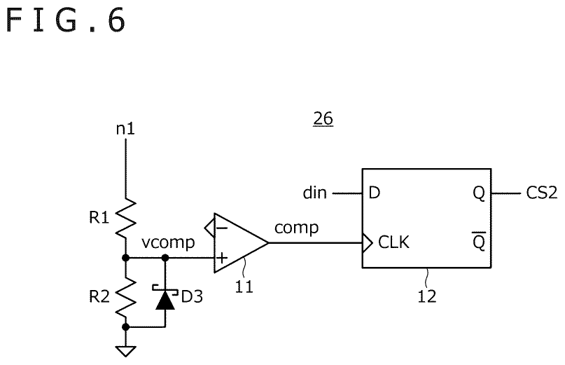

FIG. 6 is a diagram depicting a specific configuration example of the modulation unit 26. As depicted in FIG. 6, the modulation unit 26 according to the present embodiment includes a comparator 11, a D-type flip-flop circuit 12, resistors R1 and R2, and a diode D3.

The resistors R1 and R2 are provided for dividing the potential of the alternating current v1. The resistors R1 and R2 are serial-connected in this order between the node n1 and a grounded end. A connection point between the resistor R1 and the resistor R2 is connected to a non-inverted input terminal of the comparator 11. The diode D3 is a Schottky barrier diode connected in parallel with the resistor R2. The diode D3 plays a role of preventing a surge current from flowing into the comparator 11.

The comparator 11 is a circuit that compares an alternating current vcomp that results from division of the potential of the alternating current v1 at the resistors R1 and R2 with a ground potential supplied to the non-inverted input terminal, and that outputs a voltage signal comp corresponding to the comparison result. Specifically, the comparator 11 is configured to set the voltage signal comp to a high state when the alternating current vcomp is larger than the ground potential, and set the voltage signal comp to a low state when the alternating current vcomp is smaller than the ground potential.

The D-type flip-flop circuit 12 includes a clock terminal CLK, a data terminal D, an output terminal Q, and an inverted output terminal Q bar. The D-type flip-flop circuit 12 latches the value of the data terminal D at rising of the clock terminal CLK, and outputs the latched value from the output terminal Q. An output signal from the inverted output terminal Q bar is an inverted signal of an output signal from the output terminal Q. However, this signal is not used in the present embodiment. The voltage signal comp from the comparator 11 is supplied to the clock terminal CLK. A control signal din which is a low active pulse signal from the control circuit 24 is supplied to the data terminal D. An output from the output terminal Q is supplied as a control signal CS2 to the switch SWc. The control signal CS2 in FIG. 6 is a low active signal. When the control signal CS2 stays high, the switch SWc is off, and, when the control signal CS2 stays low, the switch SWc is on.

When determining that transmission of the alternating magnetic field AM is finished, the control circuit 24 keeps the control signal din activated (sets the control signal din to the low state) for a time period that is slightly shorter than one cycle of the alternating magnetic field AM. In the activated time period of the control signal din, when the voltage signal comp is changed from a low state to a high state, the control signal CS2 is activated to a low state under control of the D-type flip-flop circuit 12, and the switch SWc enters an on state. Therefore, at a timing when the alternating current v1 is changed from the negative to the positive after transmission of the alternating magnetic field AM is finished, the resonance frequency of the resonance circuit 23 is slightly changed from the first reference resonance frequency or the second reference resonance frequency.

Thereafter, the control signal din is inactivated again, and then, the voltage signal comp is changed from the low state to the high state again, whereby the control signal CS2 restores an inactivated state (goes high) and the switch SWc enters an off state under control of the D-type flip-flop circuit 12. Therefore, at a timing when the alternating current v1 is changed from the negative to the positive after the switch SWc is turned on, the resonance frequency of the resonance circuit 23 is restored to the first reference resonance frequency or the second reference resonance frequency.

Therefore, with the configuration example depicted in FIG. 6, the abovementioned operation of the modulation unit 26 can be implemented. In addition, since the rising of the voltage signal comp matches a timing at which the alternating current v1 becomes 0, the switch SWc can be turned on/off when no power (electric charge) is stored in the capacitor C. Accordingly, reduction of the level of the alternating current AC due to on/off switching of the switch SWc can be prevented.

FIGS. 7A and 7B are diagrams each depicting an example of the waveform of the alternating current v1. FIG. 7A indicates the waveform when the resonance circuit 23 is in the first state (that is, when the reference frequency is set to the first reference resonance frequency). FIG. 7B indicates the waveform when the resonance circuit 23 is in the second state (that is, when the reference frequency is set to the second reference resonance frequency). Hereinafter, an explanation of the operation of the electromagnetic induction pen 2 will be given again in view of FIGS. 7A and 7B. Further, a method in which the sensor controller 31 acquires the digital values transmitted from the electromagnetic induction pen 2, by detecting the phase of the pen signal PS will be specifically explained.

Frequencies f1 and f2 in FIGS. 7A and 7B represent the first reference resonance frequency and the second reference resonance frequency, respectively. The frequency f1 is the frequency of the alternating magnetic field AM. In addition, waveforms W1 and W2 represent waveforms on the assumption that the off state of the switch SWc is continued, and waveforms W1a and W2a represent waveforms when the modulation unit 26 performs on/off control on the switch SWc. It is to be noted that actual waveforms are gradually attenuated after transmission of the alternating magnetic field AM from the position detecting device 3 is finished, but the attenuation is omitted in FIGS. 7A and 7B.

First, in view of FIG. 7A, transmission of the alternating magnetic field AM from the position detecting device 3 is completed at time t0, and then, the completion is detected by the control circuit 24. As a result of the detection, the modulation unit 26 controls the switch SWc to be turned on at time t1 when the alternating current v1 is changed from the negative to the positive. Consequently, the resonance frequency of the resonance circuit 23 is changed from the frequency f1 by an amount equal to the capacitance of the capacitor Cx selected by the selector SEL, whereby the frequency of the alternating current signal v1 is also changed from the frequency f1 by the same amount. Thereafter, at time t2 when a next change of the alternating current v1 from the negative to the positive is made, the modulation unit 26 controls the switch SWc to be turned off, whereby the resonance frequency of the resonance circuit 23 is restored to the frequency f1, and the frequency of the alternating current signal v1 is also restored to the frequency f1.

At time t3 in FIG. 7A, a prescribed number of cycles of the frequency f1 have elapsed from time t0. If the phase of the waveform W1 is observed at time t3, “0” is obtained. In contrast, if the phase of the waveform W1a is observed, a value that is not “0” is obtained. This phase difference is generated because the frequency of the alternating current signal v1 has changed in a time from time t1 to time t2. The magnitude of the phase difference is proportional to the magnitude of the frequency change, or the capacitance of the capacitor Cx selected by the selector SEL. That is, the magnitude of the phase difference is proportional to 4-bit data transmitted from the electromagnetic induction pen 2. Thus, a table in which the correspondence between a phase and 4-bit data is defined is stored in advance in the sensor controller 31 according to the present embodiment. The sensor controller 31 is configured to obtain 4-bit data transmitted from the electromagnetic induction pen 2, by observing the phase of the pen signal PS at time t3, and by obtaining 4-bit data stored in correspondence with the acquired phase.

Next, in view of FIG. 7B, the reference resonance frequency of the resonance circuit 23 in this case is set to the frequency f2, but, when transmission of the alternating magnetic field AM from the position detecting device 3 is continued, the frequency of the alternating current v1 is set to the frequency f1. The reason is that the resonance circuit 23 is compulsorily vibrated by the strong alternating magnetic field AM. After time t0 at which transmission of the alternating magnetic field AM from the position detecting device 3 is completed, the case in FIG. 7B is the same as that in FIG. 7A, except that the frequency f1 is changed to the frequency f2. Therefore, also in this case, the sensor controller 31 can obtain 4-bit data transmitted from the electromagnetic induction pen 2 by observing the phase of the pen signal PS at time t3 when a prescribed number of the cycles of the frequency f2 has elapsed from time t0 at which transmission of the alternating magnetic field AM is finished.

The position detecting device 3 according to the present embodiment is equipped with a built-in display in which display noise having a frequency equal to the first reference resonance frequency or close to the first reference resonance frequency is generated, as previously explained. The sensor controller 31 included in the position detecting device 3 of this type sends, to the electromagnetic induction pen 2 detected through the abovementioned global scan, a switch command to make a transition of the state of the resonance circuit 23 from the first state to the second state by using the command CMD depicted in FIG. 3. Upon receiving this command, the control circuit 24 controls the switch SWa to be turned on and controls the switch SWb to be turned off by using the control signal CS1. Accordingly, the resonance circuit 23 makes a transition to the second state, and the reference resonance frequency of the resonance circuit 23 is changed to the second reference resonance frequency, whereby the sensor controller 31 can receive the pen signal PS without being under the influence of display noise. Hereinafter, a process that is performed by the sensor controller 31 according to the present embodiment will be explained in more details in view of process flowcharts which indicate a process that is executed by the sensor controller 31, with use of the frequencies f1 and f2 depicted in FIGS. 7A and 7B again.

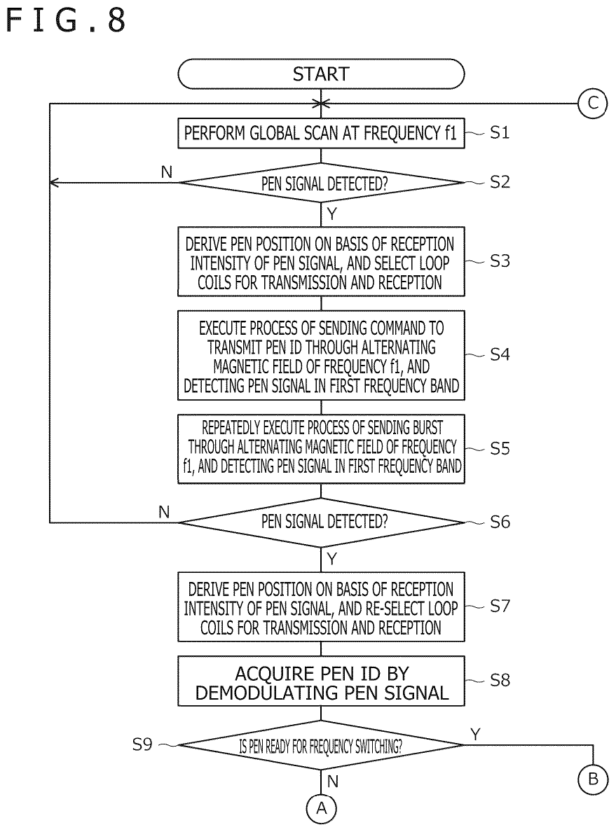

FIGS. 8 to 10 are process flowcharts each indicating a process that is executed by the sensor controller 31 according to the present embodiment. First, with reference to FIG. 8, the sensor controller 31 performs a global scan at the frequency f1 (S1). Specifically, a process of causing the plurality of loop coils LC to sequentially transmit an alternating magnetic field AM of the frequency f1 and trying to detect the pen signal PS within the first frequency band at each of the loop coils LC each time transmission of the alternating magnetic field AM is finished is performed. Then, the sensor controller 31 determines whether or not the pen signal PS is detected by the global scan at S1 (S2).

After obtaining a negative determination result at S2, the sensor controller 31 returns to S1 to perform a global scan again. On the other hand, after obtaining a positive determination result at S2, the sensor controller 31 derives the position of the electromagnetic induction pen 2, on the basis of the reception intensities of the pen signal PS at the respective loop coils LC, and selects a loop coil LC for transmission and a plurality of loop coils LC for reception on the basis of the derived position (S3). Then, a process of sending a command CMD to transmit the pen ID through the selected loop coil LC for transmission and detecting the pen signal PS through the selected plurality of loop coils LC for reception is executed (S4). Sending the command CMD at S4 is implemented by transmission of the alternating magnetic field AM of the frequency f1, and detection of the pen signal PS at S4 is implemented by signal detection within the first frequency band. The pen signal PS detected at S4 is the response signal ACK in FIG. 3.

Next, the sensor controller 31 repeatedly executes a process of transmitting a Burst by using the selected loop coil LC for transmission and detecting the pen signal PS by using the plurality of selected loop coils LC for reception (S5). Sending of the Burst at S5 is implemented by transmission of the alternating magnetic field AM of the frequency f1, and detection of the pen signal PS at S5 is implemented by signal detection within the first frequency band. The pen signal PS that is detected at S5 is DATA depicted in FIG. 3. After S5, the sensor controller 31 determines whether or not the pen signal PS has been detected as a result of S4 and S5 (S6).

When obtaining a negative determination result at S6, the sensor controller 31 returns to S1 to perform a global scan again. On the other hand, when obtaining a positive determination result at S6, the sensor controller 31 derives the position of the electromagnetic induction pen 2, on the basis of the reception intensities of the pen signal PS at the respective loop coils LC, and re-selects a loop coil LC for transmission and a plurality of loop coils LC for reception on the basis of the derived position (S7). In addition, the sensor controller 31 acquires the pen ID by demodulating the pen signal PS received by the loop coil LC where the reception intensity is the highest (S8). The demodulation at S8 is implemented by the abovementioned phase detection.

Next, on the basis of the pen ID obtained at S8, the sensor controller 31 determines whether or not the electromagnetic induction pen 2 that is under communication is an electromagnetic induction pen (frequency switching-ready pen) that is ready for reference resonance frequency switching (S9). That is, the pen ID is information that is represented by a numerical value of plural digits. The numerical value includes a numerical value representing the manufacturer of the electromagnetic induction pen 2 and a numerical value representing the version of the electromagnetic induction pen 2. The sensor controller 31 stores in advance a table in which a correspondence between a combination of the numerical value representing the manufacturer of the electromagnetic induction pen 2 and the numerical value representing the version of the electromagnetic induction pen 2 and information indicating whether or not the electromagnetic induction pen 2 is ready for frequency switching is defined. By consulting the table on the basis of the pen ID acquired at S8, the sensor controller 31 makes the determination at S9.

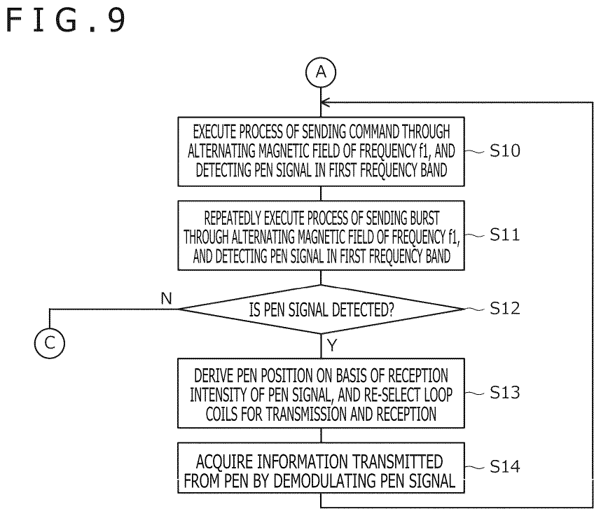

When determining that the electromagnetic induction pen 2 is not ready for frequency switching at S9, the sensor controller 31 starts a flow depicted in FIG. 9. More specifically, the sensor controller 31 first executes a process of sending the command CMD by using the loop coil LC for transmission selected at S7 and detecting the pen signal PS (response signal ACK) by using the plurality of loop coils LC for reception selected at S7 (S10). Sending the command CMD at S10 is implemented by sending the alternating magnetic field AM of the frequency f1, and detection of the pen signal PS at S10 is implemented by signal detection within the first frequency band. The content of the command CMD to be sent at S10 is not particularly limitative. The sensor controller 31 can send a desired command CMD as needed.

Next, the sensor controller 31 repeatedly executes a process of sending a Burst by using the loop coil LC for transmission selected at S7 and detecting the pen signal PS (DATA) by using the plurality of loop coils LC for reception selected at S7 (S11). Sending a Burst at S11 is implemented by transmission of the alternating magnetic field AM of the frequency f1, and detection of the pen signal PS at S11 is implemented by signal detection within the first frequency band. After S11, the sensor controller 31 determines whether or not the pen signal PS has been detected as a result of S10 and S11 (S12).

When obtaining a negative determination result at S12, the sensor controller 31 returns to S1 to perform a global scan again. On the other hand, when obtaining a positive determination result at S12, the sensor controller 31 derives the position of the electromagnetic induction pen 2, on the basis of the reception intensities of the pen signal PS at the respective loop coils LC, and re-selects a loop coil LC for transmission and a plurality of loop coils LC for reception on the basis of the derived position (S13). In addition, the sensor controller 31 acquires information transmitted from the electromagnetic induction pen 2, by demodulating the pen signal PS received by the loop coil LC where the reception intensity is the highest (S14). The demodulation at S14, which is similar to S8, is implemented by the abovementioned phase detection. Thereafter, the sensor controller 31 returns to S10 to continue the process. However, the following S10 and S11 are executed with use of the loop coil LC for transmission and the plurality of loop coils LC for reception re-selected at the last S13.

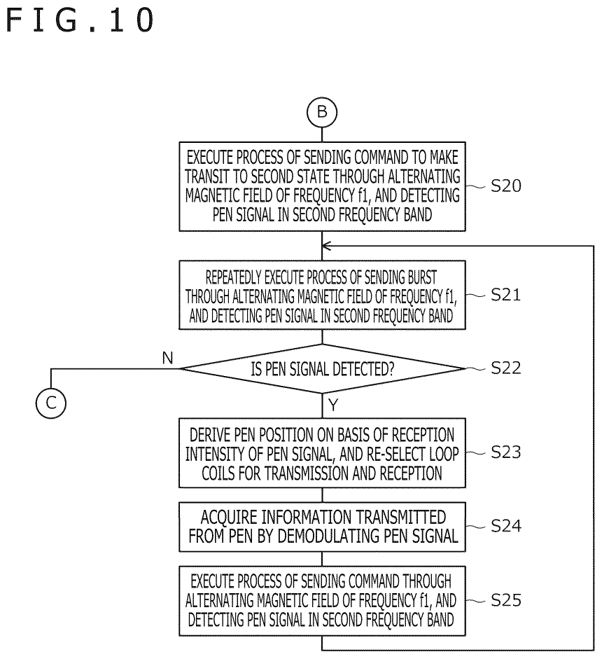

After determining that the pen is ready for frequency switching at S9 in FIG. 8, the sensor controller 31 starts a flow depicted in FIG. 10. More specifically, the sensor controller 31 first executes a process of sending a command CMD to make a transition to the second state by using the loop coil LC for transmission selected at S7 and detecting the pen signal PS (response signal ACK) by using the plurality of loop coils LC for reception selected at S7 (S20). Sending the command CMD at S20 is implemented by sending the alternating magnetic field AM of the frequency f1.

Upon receiving the command CMD sent at S20, the control circuit 24 of the electromagnetic induction pen 2 performs control to turn on the switch SWa and turn off the switch SWb. As a result of this control, the pen signal PS is transmitted in the second frequency band. Accordingly, the sensor controller 31 implements detection of the pen signal PS at S20 and subsequent steps, by signal detection within the second frequency band.

After S20, the sensor controller 31 executes acts (S21 to S25) which are similar to S11 to S14 and S10 depicted in FIG. 9. However, S21 and S25 are different from S11 and S10 in that the pen signal PS is detected by signal detection within the second frequency band at S21 and S25. Accordingly, the sensor controller 31 can detect the pen signal PS within a frequency band that is different from that of display noise, so that deterioration of the SNR of the pen signal PS due to display noise can be prevented.

As explained so far, in the position detecting system 1 according to the present embodiment, the resonance frequency of the electromagnetic induction pen 2 can be controlled by the position detecting device 3 grasping the frequency of display noise. Consequently, deterioration of the SNR of the pen signal PS due to display noise can be prevented.

The preferable embodiments of the present disclosure have been explained so far. However, it goes without saying that the present disclosure is not limited to these embodiments, and the present disclosure can be implemented by a variety of aspects within the scope of the gist thereof.

For example, the explanation of the second embodiment is based on the precondition that the frequency of the alternating magnetic field AM transmitted from the position detecting device 3 is equal to the first reference resonance frequency, but the frequency of the alternating magnetic field AM may be different from the first reference resonance frequency. However, it is preferable that the frequency of the alternating magnetic field AM be close (e.g., within 5% or 10% of) to the first reference resonance frequency which is an initial value of the resonance frequency of the resonance circuit 23 rather than the second reference resonance frequency.

In addition, the case where the frequency of the alternating magnetic field AM is maintained at a constant value has been explained in the second embodiment, but, after the sensor controller 31 sends a command to make a transition to the second state to the electromagnetic induction pen 2, the frequency of the alternating magnetic field AM may be changed to the second reference resonance or to a frequency that is closer to the second reference resonance frequency rather than the first reference resonance frequency.

The various embodiments described above can be combined to provide further embodiments. All of the U.S. patents, U.S. patent application publications, U.S. patent applications, foreign patents, foreign patent applications and non-patent publications referred to in this specification and/or listed in the Application Data Sheet are incorporated herein by reference, in their entirety. Aspects of the embodiments can be modified, if necessary to employ concepts of the various patents, applications and publications to provide yet further embodiments.

These and other changes can be made to the embodiments in light of the above-detailed description. In general, in the following claims, the terms used should not be construed to limit the claims to the specific embodiments disclosed in the specification and the claims, but should be construed to include all possible embodiments along with the full scope of equivalents to which such claims are entitled. Accordingly, the claims are not limited by the disclosure.

1. A position indicator comprising:
a resonance circuit including a coil; and
a control circuit including a memory that stores a digital value,
wherein the control circuit further includes a switch that, in operation, switches a state of the resonance circuit between a first state and a second state, wherein a first resonance frequency of the resonance circuit in the first state is different from a second resonance frequency of the resonance circuit on the second state, and,
wherein at a timing when an alternating magnetic field transmitted from a position detecting device is received, the control circuit controls the switch to set the resonance circuit to the first state, and, at a timing when the digital value stored in the memory is transmitted, the control circuit controls the switch in accordance with the digital value to be transmitted.

2. The position indicator according to claim 1, wherein,
at a timing when a value of an alternating current flowing through the resonance circuit becomes 0, the control circuit controls the switch.

3. A position detecting device for detecting a position of a position indicator, the position detecting device comprising:
a loop coil that, in operation, receives an alternating magnetic field transmitted from the position indicator; and
a sensor controller that, in operation, decodes a digital value transmitted from the position indicator, based on a frequency of the alternating magnetic field.

4. The position detecting device according to claim 3, wherein
the sensor controller, in operation, decodes the digital value transmitted from the position indicator, based on a reception level at each frequency which is obtained by frequency analysis of the alternating magnetic field.

5. The position detecting device according to claim 3, further comprising:
a plurality of loop coils, wherein
the sensor controller, in operation, derives the position of the position indicator based on reception levels of the alternating magnetic field at respective ones of the loop coils.

6. A position detecting method performed by a position detecting device that acquires information transmitted from a position indicator equipped with a resonance circuit including a coil, by detecting an alternating magnetic field transmitted from the position indicator, the method comprising:
switching, by the position indicator, a state of the resonance circuit between a first state and a second state, wherein a first reference resonance frequency of the resonance circuit in the first state is different from a second reference resonance frequency of the resonance circuit in the second state, and
sending, by the position detecting device, to the position indicator, a switch command to make a transition of the state of the resonance circuit from the first state to the second state.

7. The position detecting method according to claim 6, further comprising:
after sending the switch command, detecting, by the position detecting device, the alternating magnetic field transmitted from the position indicator, in a frequency band that includes the second reference resonance frequency of the resonance circuit in the second state but does not include the first reference resonance frequency of the resonance circuit in the first state.

8. The position detecting method according to claim 6, further comprising:
determining, by the position detecting device, whether or not the position indicator handles the switch command, based on the alternating magnetic field that is transmitted from the position indicator while the state of the resonance circuit is the first state,
wherein, in response to determining that the position indicator handles the switch command, the position detecting device sends the switch command.

9. The position detecting method according to claim 6, wherein
the position detecting device sends the switch command through an alternating magnetic field having a frequency that is same or adjacent to the first reference resonance frequency of the resonance circuit in the first state, rather than the second reference resonance frequency of the resonance circuit in the second state.

10. The position detecting method according to claim 6, wherein
the resonance circuit is in the first state when the switch command is not being received from the position detecting device.

11. The position detecting method according to claim 6, wherein
a frequency of the alternating magnetic field that is transmitted after the position detecting device sends the switch command is is same or adjacent to the second reference resonance frequency of the resonance circuit in the second state, rather than the first reference resonance frequency of the resonance circuit in the first state.

12. The position detecting method according to claim 6, wherein
a frequency of the alternating magnetic field that is transmitted after the position detecting device sends the switch command is closer to the first reference resonance frequency of the resonance circuit in the first state than the second reference resonance frequency of the resonance circuit in the second state.

13. The position detecting method according to claim 6, further comprising:
temporarily changing, by the position indicator, a resonance frequency of the resonance circuit from the first reference resonance frequency or the second reference resonance frequency by an amount corresponding to a digital value to be transmitted to the position detecting device; and
decoding, by the position detecting device, the digital value transmitted from the position indicator, by detecting a phase change of the alternating magnetic field transmitted from the position indicator.

14. The position detecting method according to claim 13, further comprising:
after sending the switch command, detecting, by the position detecting device, the alternating magnetic field transmitted from the position indicator, within a frequency band that includes the second reference resonance frequency of the resonance circuit in the second state and a resonance frequency range of the resonance circuit to which a change from the second reference resonance frequency of the resonance circuit in the second state may be made according to the digital value but does not include the first reference resonance frequency of the resonance circuit in the first state.
